(19) United States
(12) Patent Application Publication
(10) Pub. No.: US 2009/0211625 A1
(43) Pub. Date: Aug. 27, 2009

(54) PHOTOVOLTAIC MODULE WITH A WIND SUCTION SECURING DEVICE AND METHOD OF PRODUCTION

(75) Inventor: Sascha Oliver Schwarze, Berlin (DE)

Correspondence Address: DARBY & DARBY P.C., P.O. BOX 770, Church Street Station, New York, NY, 10008-0770, US

(73) Assignee: SOLON SE, Berlin (DE)

(21) Appl. No.: 12/390,210

(22) Filed: Feb. 20, 2009

(30) Foreign Application Priority Data
Feb. 21, 2008 (DE) 10 2008 010 712

(51) Int. Cl. H01L 31/048; B29C 65/48; B32B 7/08

(52) U.S. Cl. 136/251; 156/60; 156/92

(57) ABSTRACT

A photovoltaic module includes a frame structure and a plurality of wind suction securing devices. The frame structure serves to provide a predetermined spacing between a substrate and a flexible photovoltaic panel. The wind suction securing devices have a predetermined height corresponding to the predetermined spacing and are arranged in a spaced relationship on a surface of the photovoltaic panel. Each wind suction securing device includes an upper part securely attachable to the photovoltaic panel and a lower part securely attachable to the substrate. The upper and lower parts are releasably connectable to each other.

### CROSS REFERENCE TO PRIOR APPLICATIONS

Priority is claimed to German Patent Application No. DE 10 2008 010 712, filed Feb. 21, 2008, the entire disclosure of which is hereby incorporated by reference herein.

### FIELD

The present invention relates to a photovoltaic module with a bendable photovoltaic panel with a plurality of solar cell rows, which is securely, yet releasably connected to a substrate via connectors, wherein the connectors are distributed distanced from one another over the surface of the photovoltaic panel, and to a method of production.

### BACKGROUND

Among renewable energy sources, photovoltaics offers the most versatile possibilities of use on account of the modular construction of photovoltaic systems from individual photovoltaic modules (PV modules). The main application today is found in the area of consumer use, that is to say, photovoltaic systems are used for converting solar energy into electrical energy. To this end, the photovoltaic modules which accommodate the photovoltaic panels, which are constructed as a laminate and are generally bendable, must be installed on substrates which have access to sunlight. Here, what is meant is generally open spaces or roofs and facades of buildings. For photovoltaic modules on flat roofs (definition according to German Industry Standard (DIN) is up to 5° inclination) design loads with wind loads to be applied arise on the basis of DIN 1055 part 4 and DIN EN 1991-1 parts 1-4. In the case of flat roofs, the wind suction loads are of considerable importance for the dimensioning of photovoltaic systems. The determining of wind suction loads takes place in accordance with DIN 1055, part 4, DIN V ENV 1991-2-4 and the “Hinweisen zur Lastenermittlung” [guidelines for determining loads]. Theoretically, values for wind suction loads on flat roofs for the Federal Republic of Germany in Wind Zone II are to be applied between 0.82 kN/m² and 1.02 kN/m². A value with ˜1.00 kN/m² can therefore be applied for calculations. For Europe, it can be assumed that this design load must be increased further. The assumed loads for Europe correspond to the German Wind Zone III.

Wind suction occurs when the wind sweeps over the photovoltaic modules. The forces arising (“wind suction loads”) lead to a lifting/deflection upwards of the bendable photovoltaic panels. In order to withstand the wind suction loads arising, PV panels are generally enclosed and stabilized with a surrounding frame. Pure laminates are fixed on underframes with laminate clamps. As a result of the retaining of the framed standard PV modules and the laminates exclusively in the edge region, the dimensions of the PV modules are, however, severely limited in terms of length and width by their maximum deflection, which results from the wind suction loads arising.

A multiplicity of PV modules with a frame structure is described in the prior art. A spacer frame for maintaining a predetermined distance between the PV panel and a substrate is described in DE 103 61 184 B3. The problem of the deflection of the PV panel under wind suction loads is addressed here by the provision of a covering sheet of glass, which prevents the wind from sweeping directly over the PV panel, and a sheet of glass which bears over its entire surface. Both sheets of glass increase the weight and susceptibility to damage of the PV module considerably, however.

In the field of photovoltaics, a PV module is described in DE 10 2006 044 418 B3, which is supported and retained by means of frames at both of its narrow edges. Further supporting measures over the surface of the PV panel are not provided here, however. A frame structure for PV modules which allows ventilation at the rear of the PV panel is described in DE 11 2005 000 528 T5. In addition to the cooling effect, an equalization of pressure above and below the PV panel and thus at least a partial reduction in the wind suction loads is also thereby achieved. A PV module which is used for both electricity generation and making hot water is described in DE 200 22 568 U1. The PV panel is supported on the substrate by spacers. The intermediate space produced is used by passing water through it. The spacers are not explained further, but are constructed so as to be non-releasable.

A composite made of a substrate and a carrier substrate which can also be used in photovoltaics is described in DE 103 48 946 A1. Accordingly, the substrate can also be a photovoltaic panel with a plurality of solar cell rows and the carrier substrate can be a substrate of a photovoltaic module. The known composite for a temporary carrier, in the case of which a substrate which is as thin as possible is preferably mounted via connectors for processing on a substrate, is provided. The PV panel is securely connected to a substrate via rod-shaped connectors. In this case, the rod-shaped connectors are distributed over the surface of the photovoltaic panel and exhibit a distance to one another. The known connectors are, however, constructed in one piece and connected to the PV panel and the substrate, particularly by means of adhesion or a thermal bonding process. Thus, in order to release the PV panel, a massive action of force would be required thereby causing the likelihood of damage to the connection and making the module no longer suitable for renewed use. A destruction-free revision is not possible.

In the field of connecting technology, a metal plate which is securely adhesively bonded to a plastic plate via a multiplicity of rod-shaped one-piece connectors, is described in DE 100 24 764 A1. However, release is only possible by means of the action of a large force and damage. A one-piece connecting element for insulating boards, for accommodating wind suction loads, is described in EP 1 207 245 A2. A pressure equalization plate with a steep bulge is pressed into a soft insulating board. In the region of the bulge, a through hole is located, which is suitable for accommodating a screw, with the aid of which the insulating board can then be releasably connected to a metal frame. Accessibility from above is, however, a prerequisite for the use of this known connecting element.

A two-piece connecting element for connecting two components in accordance with the snap fastening principle is described in the published document DE 43 13 739 C2. In this case, it is not possible to release the connection produced without destroying the connecting element, however. A similar embodiment with a rod-shaped two-piece connector, which is used for the connection of two sheets of glass to an insulating sheet of glass, is described in DE 10 2004 054 942 A1. Even in this case, although the snap fastening principle is used, there is in turn no releasing of the connected sheets of glass provided. Finally, a two-piece rod-shaped connecting element, which is constructed releasably, is described for building scaffolding in DE 40 34 566 A1. Here, however, the connecting element is overly heavy.

### SUMMARY

In an embodiment, the present invention provides a photovoltaic module including a flexible photovoltaic panel having a plurality of solar cell rows, a frame structure providing a spacing between a substrate and the photovoltaic panel, and a plurality of wind suction securing devices configured to releasably connect the photovoltaic panel to the substrate. The wind suction securing devices have a predetermined height and are disposed in a spaced relationship about a surface of the photovoltaic panel. Each wind suction securing device includes an upper part securely attachable to the photovoltaic panel and a lower part securely attachable to the substrate. The upper and lower parts are releasably connected to each other.

### BRIEF DESCRIPTION OF THE DRAWINGS

Embodiments of the photovoltaic module with a wind suction securing device according to the present invention are described in more detail hereinafter, with reference to the schematic figures, for further understanding. In the figures:

FIG. 1 shows an exploded view of a photovoltaic module with wind suction securing devices;

FIG. 2 shows a side view of a photovoltaic module with wind suction securing devices;

FIG. 3 shows a view of a first embodiment of a wind suction securing device;

FIG. 4 shows a view of a second embodiment of a wind suction securing device;

FIG. 5 shows a longitudinal section of a third embodiment of a wind suction securing device;

FIG. 6 shows a cross section of the third embodiment;

FIG. 7 shows a side view of a fourth embodiment of a wind suction securing device; and

FIG. 8 shows a longitudinal section of a fifth embodiment of a wind suction securing device.

### DETAILED DESCRIPTION

In an embodiment, the present invention provides a special wind suction securing device for PV modules, by means of which the PV panels are on the one hand supported and on the other hand protected against wind suction so that the PV modules are no longer limited in terms of their superficial extent on account of deflection or wind suction and nevertheless a simple replacement of the PV panel is possible.

In an embodiment, the present invention provides a generic photovoltaic module with a bendable photovoltaic panel with a plurality of solar cell rows, which is securely, yet releasably connected to a substrate via connectors, wherein the connectors are distributed distanced from one another over the surface of the photovoltaic panel, in such a manner that an effective wind suction securing device results, which at the same time allows a destruction-free releasing of the bendable photovoltaic panel and substrate, however. Furthermore, a method of production of photovoltaic modules, in the case of which a wind suction securing device is provided, is provided.

In an embodiment of the photovoltaic module according to the present invention, it is provided that the connectors are constructed as at least two-piece wind suction securing devices made from an upper part and a lower part. In this case, their heights are adapted to the distance between the bendable photovoltaic panel and the substrate predetermined by a frame structure. Further, according to the embodiment, the upper part is securely connected to the bendable photovoltaic panel and the lower part is securely connected to the substrate, wherein upper part and lower part are securely, yet releasably connected to one another. A wind suction securing device of this type may be referred to as “SOLOCK”, which refers both to solar technology (SOL) and to connecting technology (LOCK), can be described by way of exemplary embodiments of the present invention. In one such embodiment, special wind suction securing devices are firstly provided by the present invention for PV modules, by means of which the bendable PV panels are on the one hand supported and on the other hand protected against wind suction. A direct consequence of these wind suction securing devices is the possible enlargement of the PV panel surfaces. In this case, the wind suction securing devices hold the bendable PV panels on the one hand so that they cannot sag as a result of their own weight during operation. On the other hand, the wind suction securing devices also protect the bendable PV panels against deflection upwards as a result of wind suction loads that are being applied. By means of the division in two, the wind suction securing device according to an embodiment of the present invention at the same time also allows individual PV panels to be lifted out for maintenance work or replacement in a manner that is unproblematic and destruction-free. To this end, only the wind suction securing devices are to be released. Preferably, the wind suction securing device consists of an upper part and a lower part, which can be releasably connected to one another by means of their shaping and, if appropriate, by means of additional components. As a result, during operation, a secure connection always exists between the bendable PV panel and the substrate. In one embodiment, by means of the combination of all provided wind suction securing devices which are arranged uniformly and with distance over the surface of the PV panel it can thus be ensured that the bendable PV panel does not unnecessarily deflect upwards under the influence of wind suction. In the event of maintenance or a replacement of the PV panel, all wind suction securing devices are correspondingly released in a destruction-free manner. Thereafter, the PV panel can be secured again with the same elements, or a prepared replacement PV panel, which on its lower side carries the corresponding upper parts of the wind suction securing device in the corresponding arrangement, can be put on and securely connected on the substrate by means of the lower parts.

The upper part of the wind suction securing device is, depending on the static requirements, fixed to the reverse side of the PV panel. The lower part is, depending on the installation situation, if appropriate connected to a counter bearing. Adhesive and/or screw connections can, depending on the requirement, be selected for fixing the wind suction securing device. As a result of the shaping and the two part construction, the PV panel can be released from the substrate in a destruction-free manner. As a result of the locking of the wind suction securing device, a bearing is produced, which is in the position to divert pulling forces from the PV panel into the substructure. Using the wind suction securing device according to such an embodiment of the present invention, larger PV modules can thus be realized in terms of their length and width without having to increase the cross sections of the carrying frame structure. The deflection in the case of wind suction loads being applied can be reduced considerably. This means that a failure of the PV module as a result of deflection, which means stress for the solar cells and the cell connector, occurs much less frequently. The wind suction securing device according to the invention can be used in the case of PV modules which lie horizontally and also in the case of PV modules which are mounted on two sides. Even use as a facade retaining device is possible.

On account of the predetermined distance between the PV panel and substrate, the wind suction securing devices preferably have an elongate, rod-shaped construction. Other construction shapes, for example, block or sphere-shaped are likewise readily possible, however. In another embodiment of the photovoltaic module, it is provided that the upper part and the lower part are connected to the photovoltaic panel or the substrate by means of an adhesive bond or a screw connection. A positive or one-piece connection is likewise possible.

It can further preferably be provided that the lower part of the wind suction securing device is constructed as a plug-in shaft which has a plug-in plate with a diameter larger than the plug-in shaft at its end which faces the photovoltaic panel. The length of a plug-in shaft of this type can simply be adjusted to the space conditions present. For force distribution, it can advantageously be securely connected to a base plate. In terms of material, it can, for example, consist of metal or also of a plastic, for example, polyamide. In this case, the material can also be opaque, as no disturbing arrangement in the area subject to the incidence of light is provided. This embodiment can be used with a plug-in shaft in the case of glass-glass modules, PV panels with bifacial cells or PV panels with transparent film on the rear side. The upper part of the wind suction securing device is then correspondingly constructed as a plug-in bracket with a lateral accommodation opening for the plug-in shaft on the end which faces the substrate, wherein the plug-in bracket is, for example, constructed from clear polymethyl-methacrylate (PMMA) and is therefore light-permeable, so that no reduction in the amount of incident light occurs as a result of the wind suction securing devices. Additionally, the plug-in bracket may be provided with an undercut for the plug-in plate, so that the plug-in plate of the plug-in shaft, following the latter's insertion into the plug-in bracket through the lateral accommodation opening, slips over the undercut, so that an axial pulling apart of the plug-in shaft and the plug-in bracket into the unconnected position is avoided. A secure connection possibility of the plug-in shaft and the plug-in bracket in accordance with the bayonet principle is produced. For the simultaneous insertion of all plug-in shafts into the provided plug-in brackets, it is preferable that the accommodation openings of the plug-in bracket of all provided wind suction securing devices are orientated in the same direction.

In another embodiment of the wind suction securing device according to the present invention, it can be provided that the lower part of the wind suction securing device is constructed as a pin receptacle with two azimuthal slots, which are diametrically opposite each other. The upper part of the wind suction securing device is then constructed as a pin with an azimuthal circumferential groove. The pin is plugged into the pin receptacle. As a result of the engagement of an omega spring through the slots into the circumferential groove, an axial pulling out is prevented. The omega spring can be pulled out relatively simply manually or with an offset tool. The insertion can likewise take place manually or with the offset tool. In order, in this case, to achieve a good accessibility of the wind suction securing device, it is preferable if the wind suction securing devices are arranged in the edge region of the photovoltaic module. Otherwise, correspondingly long tools must be used to lock and unlock the wind suction securing devices.

In yet another embodiment, the upper part and lower part of the wind suction securing device can advantageously be constructed according to the snap fastening principle. Preferably, in this case, the upper part of the wind suction securing device is constructed as a ball end and the lower part is constructed as a ball socket with elastic ribs. The elastic ribs are pressed against the ball end by a spring ring, in order to generate the required retention force between the upper and lower parts under wind suction loading. When inserting the ball end into the ball socket, the ribs are correspondingly pushed back. Thus, the upper and lower parts are constructed in such a manner that a destruction free separation and renewed connection is possible.

By means of the wind suction securing device according to the invention, a photovoltaic panel can be coupled in a wind suction secure manner to virtually any desired substrate in horizontal, vertical or inclined orientation. The wind suction securing device is particularly suitable when the substrate is constructed as a lightweight building slab or as a facade panel. Particularly in the case of a lightweight building slab, the plug-in shaft of a wind suction securing device can engage through the lightweight building slab and be supported with respect to the lightweight building slab with at least one pressure distribution panel. A secure coupling to the relatively sensitive lightweight building slab therefore possible without being impaired by means of the action of force on account of the dissipated wind suction loads.

In turn, any desired PV panel with the wind suction securing device according to various embodiments of the present invention can also be secured against impinging wind suction loads. Any type of laminate or substrate which is as thin as possible can be used on a carrier substrate. As a result of the distance between the photovoltaic panel and the substrate, which is predetermined by means of the height of the wind suction securing devices or by means of the frame structure and is generally used for ventilation at the rear of the solar cells, photovoltaic panels which are active on both sides (so-called “bifacial panels” with a coating with solar cells on both surfaces) can also be used. In order to be able to use the light falling between the solar cell rows on the underside of PV panels of this type, it is in this case preferable for a reflector foil to be arranged on the substrate. The lower parts of the wind suction securing devices then engage through the reflector foils into the substrate, for example, a lightweight building slab.

The number and distribution of the required wind suction securing devices over the surface of a PV panel is to be adjusted individually in accordance with its size, thickness and arrangement and application. In the case of thicker PV modules, less wind suction securing devices are needed than in the case of thin ones and less in the case of small ones than in the case of big ones. It is preferable, in the case of standard PV modules, if two wind suction securing devices are provided over the width of the photovoltaic module and so many wind suction securing devices are provided over its length that there are always three solar cell rows running transversely between two wind suction securing devices. An optimal wind suction securing device can be provided by a distribution of this type and the outlay (even in the case of assembly) therefor can be minimized. In connection with this, it is noted that a relatively simple method of production for simultaneous orientation and simple stopping of all wind suction securing devices results when all lower parts of the wind suction securing devices are first connected to the substrate and then all upper parts are connected to the lower parts. Subsequently, all upper parts are then wetted with adhesive at their ends which face the photovoltaic panel. After that, the photovoltaic panel is placed on all upper parts, so that the upper parts enter into a secure connection to the photovoltaic panel. The PV panel is thus coupled on in a wind suction securing manner, but may be released.

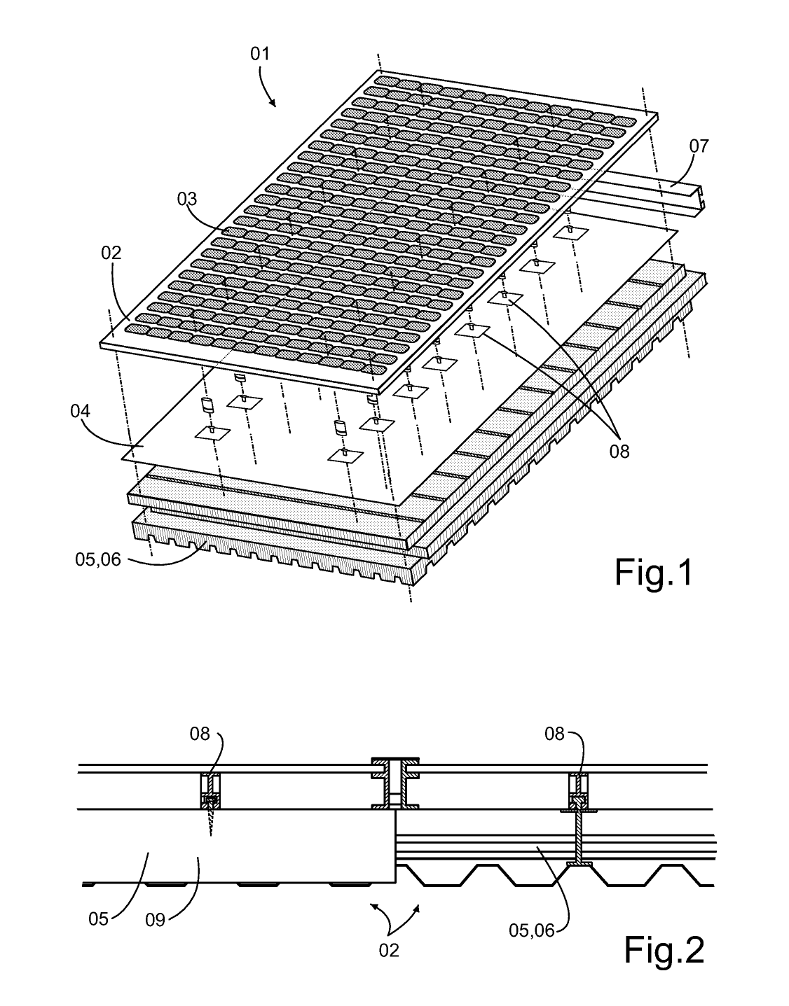

FIG. 1 shows an exploded view of a photovoltaic module 01 (PV module) according to the invention with a bendable photovoltaic panel 02 (PV panel) with a plurality of solar cell rows 03. These are constructed bifacially so that light can also be shone in onto the underside of the bendable PV panel 02 by means of a reflector foil 04 and used. A lightweight building slab 06 is used as the substrate 05 in the exemplary embodiment shown. The PV module 01 is closed off at least at the narrow sides by frame structures 07 which define the installation distance between the PV panel 02 and the substrate 05. A multiplicity of wind suction securing devices 08 are distributed as connectors uniformly and at a distance over the surface of the PV panel 02, which wind suction securing devices 08 mount the PV panels 02 in a secure connection so that they cannot be deflected either under compressive force (gravity, deflection downwards) or by tensile force (wind suction force/load, deflection upwards). The solar cells 03 or the PV module 01 can thus not be adversely affected by deflection.

With an approximate length of the PV module 01 of 1830 mm, 8 wind suction securing devices 08 can be provided over the length, so that there are always 3 solar cell rows 03 between two wind suction securing devices 08. With a width of the PV module 01 of approximately 1000 mm, 2 wind suction securing devices 08 over the width are sufficient, so that a total of 16 wind suction securing devices 08 are sufficient for a PV module 01 of the exemplary specified size. The height of the wind suction securing devices 08 is adapted to the predetermined installation distance between the PV panel 02 and substrate 05, they basically have a two-part structure.

FIG. 2 shows a side view of two adjacent PV modules 02, with the left-hand PV module 02 showing the substrate 05 with a substrate covering 09 and the right-hand PV module 02 showing the substrate 05 directly in the form of a lightweight building slab 06. Furthermore, 2 wind suction securing devices 08 are shown. The two left-hand wind suction securing devices 08 engage in the substrate covering 09, the two right-hand wind suction securing devices 08 engage into the lightweight building slab 06.

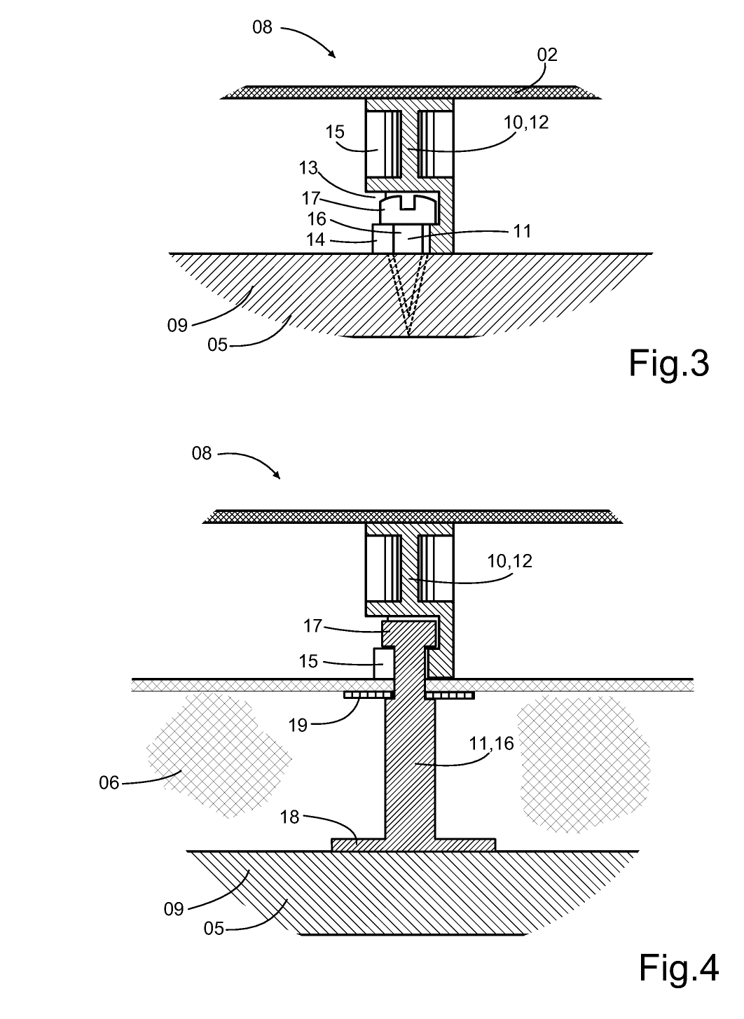

FIG. 3 shows a detail in the region of a wind suction securing device 08 which engages in the frame covering 09. Each wind suction securing device 08 consists basically of an upper part 10 and a lower part 11, with the upper part 10 being securely connected to the PV panel 02 and the lower part 11 being securely connected to the substrate 05, for example by adhesive bonding or screw connection. Upper part 10 and lower part 11 are connected securely, but releasably to each other.

In FIG. 3 the upper part 10 of the wind suction securing device 08 is constructed as a cylindrical plug-in bracket 12 with a lateral accommodation opening 13, which is provided on the end which faces the substrate 05, with an undercut 14. Four recesses 15 are provided in the plug-in bracket 12 to reduce the weight and improve handling. In order to avoid influencing the light, the plug-in bracket 12 may be produced from transparent PMMA. The lower part 11 of the wind suction securing device 08 consists in this embodiment of a simple screw as the plug-in shaft 16, whose cheese head forms a plug-in plate 17 which engages behind the undercut 14 in the upper part 10 so that an axial separation of upper part 10 and lower part 11 is not possible. Unlocking of the wind suction securing devices 08 for removal of the PV panel 02 takes place by means of a lateral movement in the opposite direction. In this embodiment it is to be noted that the accommodation openings 13 of all the provided wind suction securing devices 08 are orientated the same way. For connection, for example after a check, the PV panel 02 with the upper parts 10 of the wind suction securing devices 08 fastened thereon is placed on the substrate with the accommodation openings 13 adjacent to the lower parts 11. The PV panel 02 is then pushed laterally in such a manner that all the plug-in shafts 16 are pushed into the accommodation openings 13 and the plug-in plates 17 engage into the undercuts 14.

The above-described assembly method relates to the single arrangement of a PV module 01. In a matrix-like arrangement of a multiplicity of PV modules 01 in a photovoltaic system it should be noted with a bayonet-type embodiment of the wind suction securing devices 08 that the gaps between the individual PV modules 01 are sufficiently wide to allow the lateral displacement movements of the PV panel 02 to be carried out for assembly and disassembly purposes. Although with an embodiment of the wind suction securing device 08 with an omega spring (see below), no lateral displacement is necessary, the gap is designed to be so wide that access to the wind suction securing devices 08 is possible. Alternatively, this embodiment is preferably arranged only in the accessible edge region of the PV module 01. No restrictions are produced with an embodiment of the wind suction securing device 08 according to the snap-fastening principle (see below). Assembly and disassembly of the PV panel 02 takes place exclusively by raising or lowering it. Accessibility to the wind suction securing devices 08 through the gaps between the individual PV modules 01 or from the edge of the PV modules 01 is not necessary here.

During an initial assembly of a PV panel 02 it is particularly simple if the lower parts 11 are first connected to the substrate 05. The upper parts 10 are then inserted and locked and provided with adhesive on their upper side. The PV panel 02 is then pressed onto the adhesive upper parts 10 so that correct positioning of the upper and lower parts 10, 11 of all the wind suction securing devices 08 in the locked state is produced automatically. This simplified initial assembly can be used in all the embodiments of the wind suction securing device 08 mentioned.

FIG. 4 shows a detail in the region of a wind suction securing device 08 which engages in the region of the lightweight building slab 06. The upper part 10 of the wind suction securing device 08 is constructed identically to the upper part 10 according to FIG. 3 as a cylindrical plug-in bracket 12 consisting preferably of PMMA. The lower part 11 consists in this case however of a long plug-in shaft 16 which penetrates the lightweight building slab 06. The plug-in shaft 16, which consists, for example, of opaque polyamide (PA), is securely connected at the bottom to a base plate 18. The plug-in plate 17 at the top end is constructed as a small cylinder which engages behind the recess 15 in the plug-in bracket 12. In order to distribute load and thus avoid damage to the relatively soft lightweight building slab 06, another pressure distribution panel 19 is provided on the surface of the lightweight building slab 06 at the top end of the plug-in shaft 16. The base plate 18 likewise has load distribution functions.

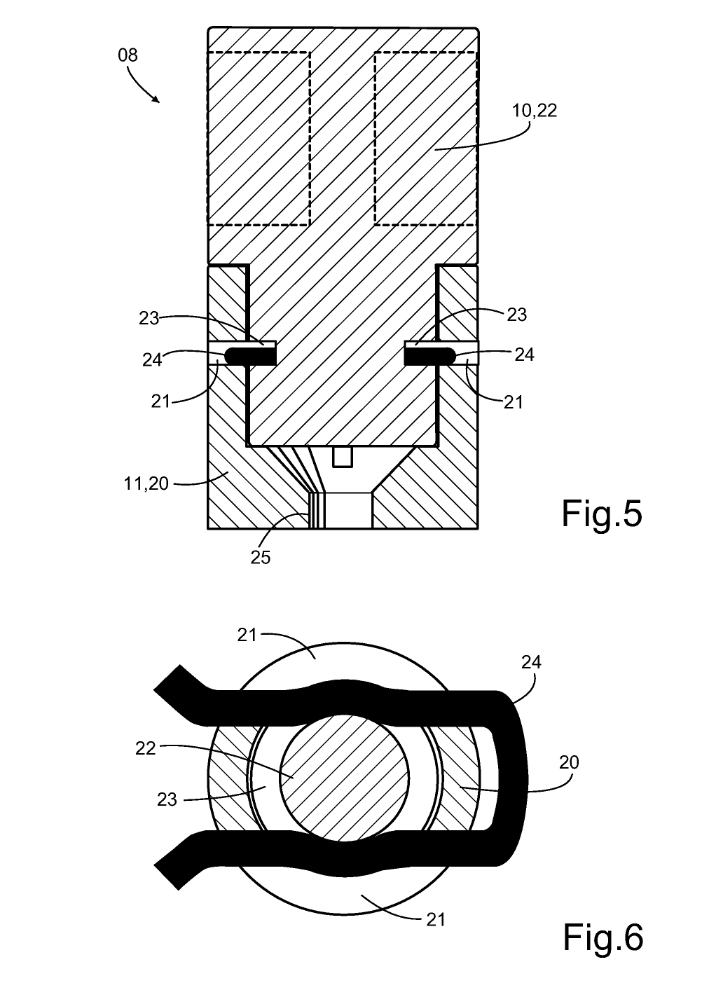

FIG. 5 shows a longitudinal section of a third embodiment of a wind suction securing device 08. The lower part 11 is in this case constructed as a pin receptacle 20 with two diametrically opposite azimuthal slots 21 and the upper part 10 is constructed as a pin 22 with an azimuthal circumferential groove 23. In the locked state of the wind suction securing device 08, an omega spring 24 engages through the slots 21 into the circumferential groove 23 and prevents the upper and lower parts 10, 11 from being pulled apart axially. The pin receptacle 20 has another through hole 25 for connecting to the substrate 05. A special screw can for example be guided through the through hole 25, which engages in an insulant dowel in the lightweight building slab 06 consisting of hard foam.

FIG. 6 shows a section diagram just above the omega spring 24 of the pin receptacle 20 with the two slots 21 and the pins 22 with the circumferential groove 23 into which the omega spring 24 engages through the slots 21.

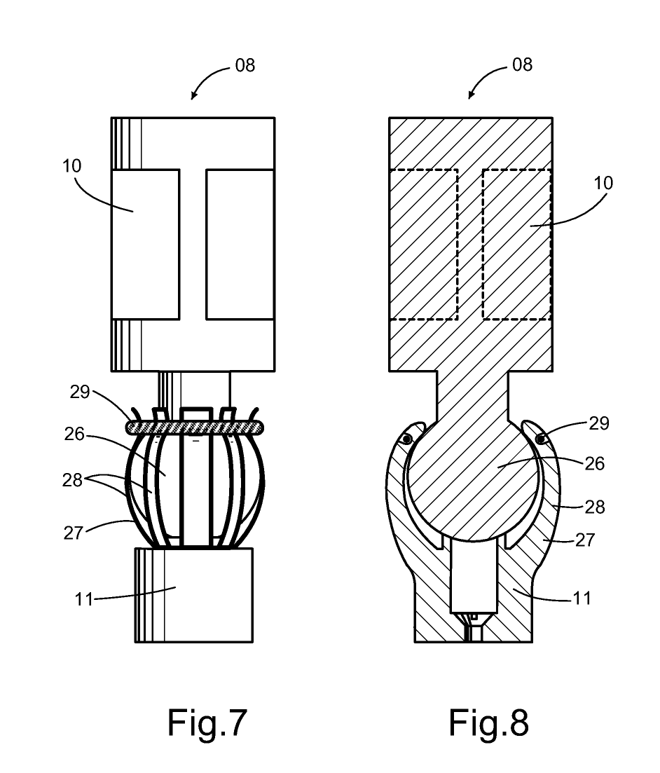

FIG. 7 shows a side view of a fourth embodiment and FIG. 8 shows a longitudinal section of a fifth possible embodiment of the wind suction securing device 08 according to the recloseable snap-fastening principle. The upper part 10 has a ball end 26 which is securely connected to the PV panel 02 for example by adhesive bonding or screw connection. This engages into a ball socket 27 on the lower part 11 of the wind suction securing device, which is likewise securely connected to the substrate 05 by adhesive bonding or screw connection (see through hole). The ball socket 27 or the whole lower part 11 are produced for example from steel (FIG. 7) or plastic (FIG. 8), so that the individual ribs 28 are indeed bendable and do not break off when bent back by the ball end 26. The retaining force on the ball end 26 is achieved by the pressure of the ribs 28 on the ball end, with an intensification of the force being achieved by means of a ring spring 29, for example in the embodiment of a helical spring (FIG. 7) or an O-ring (FIG. 8). This means that the wind suction securing device 08 can function reliably and protect the PV panel 02 from damage owing to impermissible deflection upwards by impinging wind suction loads and in the process nevertheless allow rapid, simple and cost-effective disassembly, initial assembly or reassembly of the photovoltaic panel 02.

The present invention is not limited to the exemplary embodiments described herein; reference should be had to the appended claims.

REFERENCE LIST

| | |
|---|---|
| 01 | Photovoltaic module |
| 02 | Photovoltaic panel |
| 03 | Solar cell row |
| 04 | Reflector foil |
| 05 | Substrate |
| 06 | Lightweight building slab |
| 07 | Frame structure |
| 08 | Wind suction securing device |
| 09 | Substrate covering |
| 10 | Upper part |
| 11 | Lower part |
| 12 | Plug-in bracket |
| 13 | Accommodation opening |
| 14 | Undercut |
| 15 | Recess |
| 16 | Plug-in shaft |
| 17 | Plug-in plate |
| 18 | Base plate |
| 19 | Pressure distribution panel |
| 20 | Pin receptacle |
| 21 | Slot |
| 22 | Pin |
| 23 | Circumferential groove |
| 24 | Omega spring |
| 25 | Through hole |
| 26 | Ball end |
| 27 | Ball socket |
| 28 | Rib |
| 29 | Ring spring |

1. A photovoltaic module comprising:
a flexible photovoltaic panel having a plurality of solar cell rows;
a frame structure providing a predetermined spacing between the photovoltaic panel and a substrate; and
a plurality of wind suction securing devices configured to releasably connect the photovoltaic panel to the substrate, each of the wind suction securing devices having a height corresponding to the predetermined spacing and being disposed in a spaced relationship with respect to each other on a surface of the photovoltaic panel, each wind suction securing device having at least an upper part and a lower part, wherein the upper part is securely attachable to the photovoltaic panel and the lower part is securely attachable to the substrate, and wherein the upper part and lower part are releasably connectable to each other.

2. The photovoltaic module according to claim 1, wherein the wind suction securing devices have an elongated, rod-like shape.

3. The photovoltaic module according to claim 1, wherein the upper and lower parts are connectable to the photovoltaic panel and the substrate, respectively, via at least one of adhesive bonding and a screw connection.

4. The photovoltaic module according to claim 1, wherein the lower part includes a plug-in shaft having a plug-in plate disposed on a panel-facing end of the plug-in shaft and the upper part includes a plug-in bracket having a laterally disposed accommodation opening with an undercut proximate a substrate-facing end of the plug-in bracket.

5. The photovoltaic module according to claim 4, wherein the plug-in plate has a larger cross-section than the plug-in shaft and the accommodation opening is adapted to receive the plug-in shaft such that the undercut is at least partially disposed beneath the plug-in plate.

6. The photovoltaic module according to claim 5, wherein the accommodation opening of each upper part of each wind suction securing device is similarly oriented.

7. The photovoltaic module according to claim 4, wherein the plug-in shaft is securely attached at a substrate-facing end to a base plate.

8. The photovoltaic module according to claim 1, wherein the lower part includes a pin receptacle having two diametrically-opposed azimuthal slots and the upper part includes a pin having a corresponding circumferential azimuthal groove such that the upper and lower parts are connectable via an omega spring extending into the slots and the groove.

9. The photovoltaic module according to claim 8, wherein the wind suction securing devices are disposed in an edge region of the photovoltaic module.

10. The photovoltaic module according to claim 1, wherein the upper part includes a ball end and the lower part includes a corresponding ball socket having elastic ribs such that the upper and lower parts are connectable via a spring ring pressing the ribs against the ball end.

11. The photovoltaic module according to claim 1, wherein the substrate is at least one of a lightweight building slab and a façade panel.

12. The photovoltaic module according to claim 4, wherein the substrate is a lightweight building slab and wherein the plug-in shaft engages through the lightweight building slab and is supported with respect thereto via at least one pressure distribution panel.

13. The photovoltaic module according to claim 1, wherein the photovoltaic panel is active on the surface and on an opposite surface thereof, and a reflector foil is provided on a panel-facing surface of the substrate.

14. The photovoltaic module according to claim 1, wherein the wind suction securing devices are disposed such that there are at least two wind suction securing devices provided between each three rows of the solar cell rows.

15. The photovoltaic module according to claim 1, wherein the upper part includes clear polymethyl-methacrylate.

16. The photovoltaic module according to claim 1, wherein the lower part is composed of opaque polyamide.

17. A method of producing a photovoltaic module including a plurality of wind suction securing devices each having a releasable upper and lower part, the method comprising:
attaching the lower parts to a substrate;
releasably connecting the upper and lower parts of each wind suction securing device;
applying an adhesive to a panel-facing end of each of the upper parts; and
fixing a photovoltaic panel onto the panel-facing ends of the upper parts.

18. The method of producing a photovoltaic module of claim 17, wherein the lower parts are attached to the substrate using at least one of a screw connection and a base plate having an adhesive thereon.

19. The method of producing a photovoltaic module of claim 17, wherein the lower part includes a plug-in shaft having a plug-in plate disposed on a panel-facing end of the plug-in shaft and the upper part includes a plug-in bracket having a laterally disposed accommodation opening with an undercut proximate a substrate-facing end of the plug-in bracket, and wherein the upper and lower parts are releasably connected by inserting the plug-in shaft into the accommodation opening such that the undercut is at least partially disposed beneath the plug-in plate.

20. The method of producing a photovoltaic module of claim 17, wherein the upper and lower parts are releasably connected using a spring and at least one of corresponding azimuthal grooves and slots and corresponding ball ends and ball sockets.
